(19) United States
(12) Patent Application Publication
(10) Pub. No.: US 2011/0025134 A1
(43) Pub. Date: Feb. 3, 2011

(54) CAPACITOR ARRANGEMENT AND HIGH-VOLTAGE PULSE GENERATOR HAVING SUCH A CAPACITOR ARRANGEMENT

(75) Inventor: Fredrik Olsson, Orebro (SE)

Correspondence Address: CONNOLLY BOVE LODGE & HUTZ LLP, 1875 EYE STREET, N.W., SUITE 1100, WASHINGTON, DC, 20006, US

(73) Assignee: BAE Systems Bofors AB

(21) Appl. No.: 12/921,031

(22) PCT Filed: Feb. 25, 2009
(86) PCT No.: PCT/SE09/00105

§ 371 Date: Oct. 18, 2010

(30) Foreign Application Priority Data
Mar. 6, 2008 (SE) 0800517-5

(51) Int. Cl. H03K 3/00; H01G 4/38

(52) U.S. Cl. 307/108; 361/328

(57) ABSTRACT

The invention relates to a capacitor arrangement (1) comprising at least one capacitor (2) having a first electrode (3) connected to a first conductive element (13) and a second electrode (4) connected to a second conductive element (14). The first and second conductive elements (13, 14) of the capacitors are separated by a dielectric (15). The integral capacitors are configured to each form a substantially circular-cylindrical body having a central through opening (17). By virtue of the invention, a compact capacitor arrangement is achieved, which minimizes the risk of electrical sparkovers. The invention is obtained by the introduction of four electrodes, a first and a second electrode (3, 4) being placed adjacent to the outer peripheral surface (18) of the body, whilst a third and a fourth electrode (7, 8) are placed adjacent to the central opening (17) of the body.

The present arrangement relates to a capacitor arrangement comprising at least one capacitor having a first electrode connected to a first conductive element and a second electrode connected to a second conductive element, which first and second conductive elements are separated by a dielectric and which integral capacitors are configured to each form a substantially circular-cylindrical body having a central through opening. The invention also relates to a high-voltage pulse generator having such a capacitor arrangement.

The invention is suitable for use in high-voltage equipment and, for example, for incorporation in a Marx generator.

A capacitor arrangement according to the above is previously known through US patent specification U.S. Pat. No. 4,645,941. The capacitor arrangement is incorporated in a pulse generator of the Marx generator type. The capacitors forming part of the capacitor arrangement comprise two electrodes each, which are used both for charging and for discharging of an associated capacitor. The charging of the capacitor is carried out on the outermost parts of the electrodes, whilst the discharging is carried out by that part of the electrodes which extends in towards the central through opening. The discharging takes place in the axial direction and the UV radiation which is formed in a spark gap is not sufficient to trigger a next gap. An external triggering source is therefore provided to cater for the triggering of spark gaps included in the capacitor arrangement.

The electrode arrangement according to the said U.S. patent specification limits the structure of the capacitor arrangement in several respects. This applies, inter alia, to the prospects of making the capacitor arrangement more compact. One reason for this is that the axially arranged spark gaps take up a lot of space. Another reason is that the solution comprising two electrodes which extend from the peripheral parts of the capacitors into the central opening severely limits the capacitor type. In principle, because of the configuration of the two electrodes, the capacitor type is limited to a construction having a flat dielectric between two flat metal discs. In order to activate the capacitor arrangement, moreover, an external triggering source is required, since the discharging takes place axially and generated UV radiation from the respective gap will not therefore trigger the next gap.

The objects of the present invention are to provide a capacitor arrangement which is compact, which does not require an external triggering source and which minimizes the risk of electrical sparkovers.

The objects of the invention are achieved by a capacitor arrangement according to the first paragraph above, characterized in that the first and second conductive elements comprise a further electrode, each respectively defined as the third and fourth electrode, the first and third electrodes being connected to the first conductive element and the second and fourth electrodes being connected to the second conductive element, and the first and second electrodes belonging to a capacitor being placed adjacent to the outer peripheral surface of the body, whilst the third and fourth electrodes are placed adjacent to the central opening of the body, and also by a generator having such a capacitor arrangement. The introduction of separate systems for charging and discharging of the capacitors reduces the risk of electrical sparkovers at the charging electrodes. Through the introduction of four electrodes, the freedom of choice from amongst known capacitor versions is increased and, moreover, new capacitor constructions can also be developed. The proposed construction per se, and the freedom to choose a capacitor design, contributes to a compact construction in which the risk of electrical sparkovers can be minimized.

According to one advantageous embodiment, the first and second electrodes of a capacitor are arranged diagonally on the outer periphery of the body. Advantageously, the third and fourth electrodes of a capacitor are also arranged diagonally on the body in its central opening. In addition, the first and second electrodes of a capacitor are expediently arranged axially offset. The offsetting, in the axial direction, of the third and fourth electrodes in the central opening means that a structure can be created which allows the creation of a substantially radial spark gap. By virtue of the above-proposed structural arrangements, symmetries are created which are favourable to achieving a compact capacitor arrangement, which at the same time allows the simple and effective generation of pulses with high energy density.

In order to achieve an even more radial spark gap, the spark gap can also be displaced within the capacitor arrangement. One embodiment is here characterized in that an electric wire with spark gap electrode is connected to each of the third and fourth electrodes for displacement of the spark gap in the axial direction. In this way, the spark gap electrodes of adjoining capacitors can be orientated directly one in front of the other in the radial plane.

Preferably, the capacitors forming part of the capacitor arrangement are arranged in a line in the axial direction and a switch element is included in the centre between each of the integral capacitors. The configuration of the capacitors in combination with the central placement of the switches makes the proposed capacitor arrangement very compact.

According to the invention, wide latitude is created in the choice of capacitors. According to a first proposed embodiment of the capacitors, the capacitor arrangement is characterized in that the first and second conductive elements of a capacitor are separated in the axial direction by the dielectric. Capacitors built according to this first proposed embodiment are relatively simple in their construction and are easy to introduce into a capacitor arrangement.

According to a second proposed embodiment of the invention, the capacitor arrangement is characterized in that the first and second conductive elements of a capacitor are separated in the radial direction by the dielectric. Advantageously, the first and second conductive elements and the dielectric of a capacitor are here configured to form a coil shape. The embodiment affords wide latitude in the design of the capacitors. Inter alia, parameters such as number of turns, thickness of the dielectric and width in the axial direction can be chosen according to what is found to be suitable in the embodiment in question.

The capacitor arrangement, and especially its electrodes, is expediently enclosed in cavities containing protective gas. According to one embodiment of the capacitor arrangement, it is therefore proposed that an outer cavity is arranged to enclose the first and second electrodes of integral capacitors, whilst an inner cavity is arranged to enclose the third and fourth electrodes of integral capacitors. Through the introduction of cavities, the most favourable possible environment is created for enclosed components, with the facility, inter alia, to choose a suitable gas and suitable pressure.

The invention will be further described below by means of illustrative embodiments, with reference to the appended, non-scale drawings, in which:

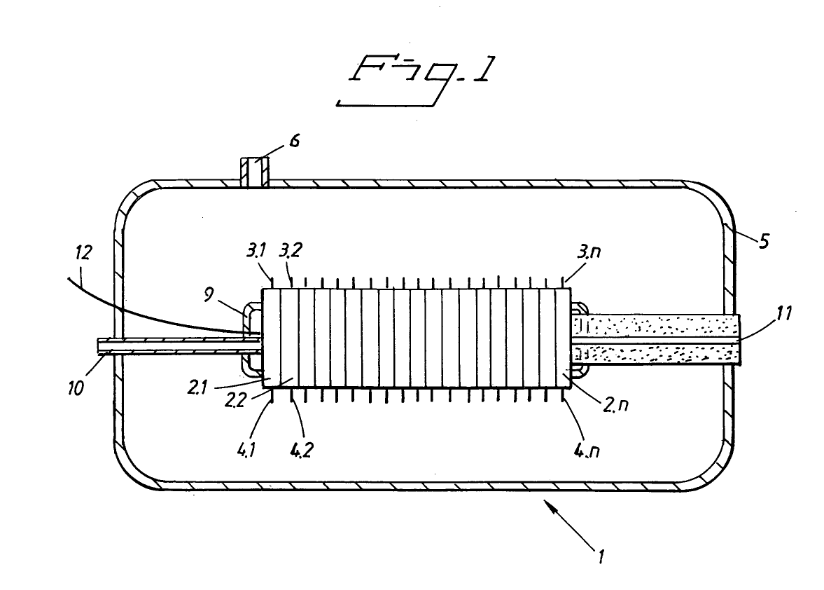

FIG. 1 shows schematically, partly in sectioned view, one example of a capacitor arrangement which can be incorporated in a Marx-type generator,

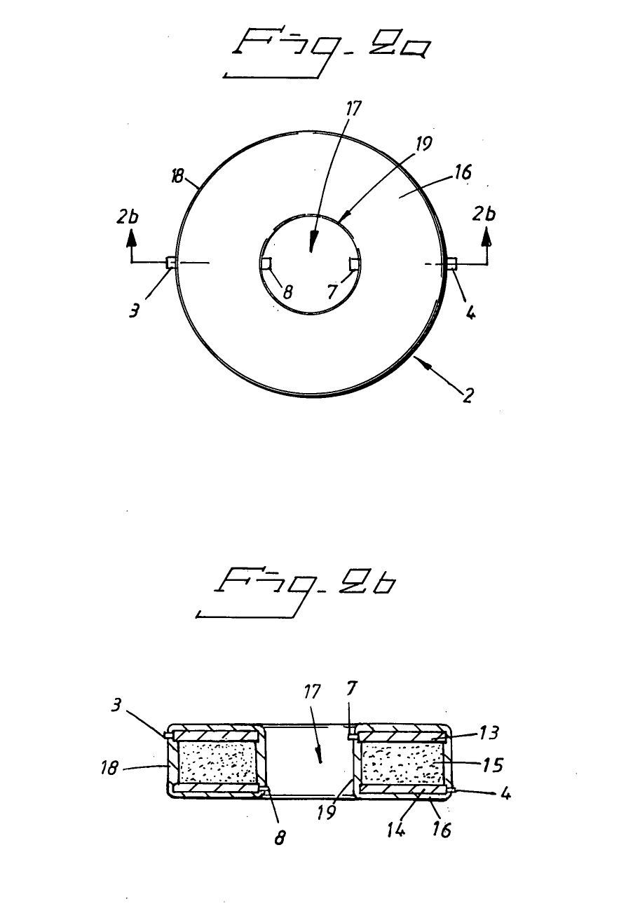

FIG. 2a shows schematically a first example of the structure of a capacitor forming part of a capacitor arrangement according to the invention, in side view,

FIG. 2b shows schematically the capacitor according to FIG. 2a, viewed in a section 2b-2b marked in FIG. 2a,

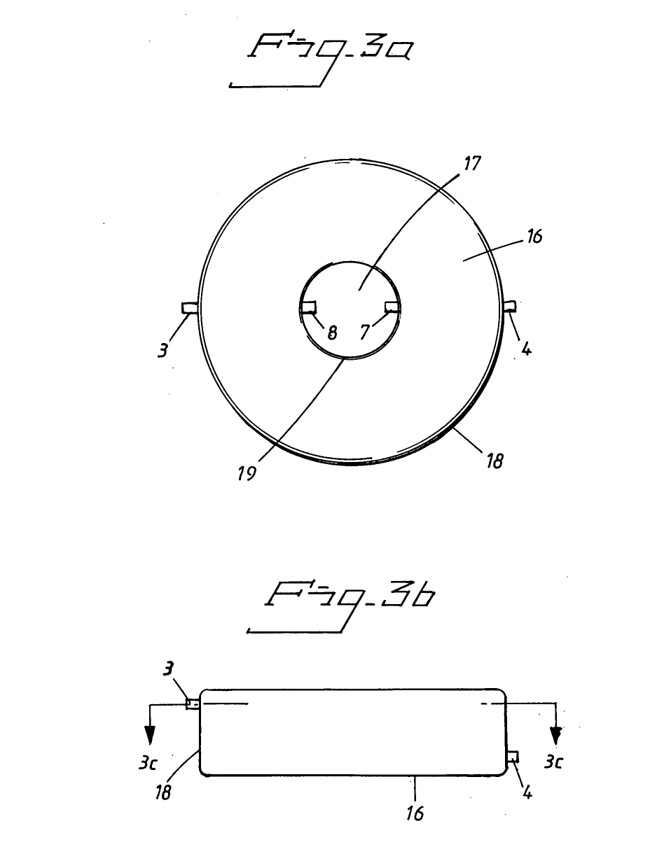

FIG. 3a shows schematically a second example of the structure of a capacitor forming part of a capacitor arrangement according to the invention, in side view,

FIG. 3b shows schematically a top view of the capacitor according to FIG. 3a,

FIG. 3c shows schematically a section through the capacitor according to FIGS. 3a and 3b and marked as a section 3c-3c in FIG. 3b,

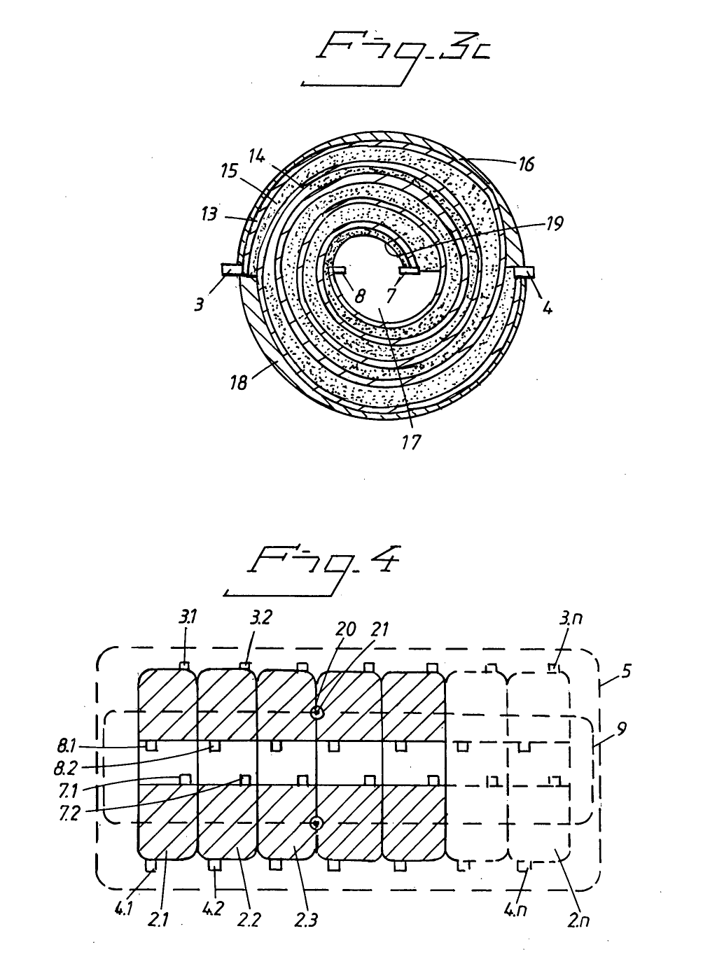

FIG. 4 shows schematically, via a central section, the structure of an electrode arrangement in a line of capacitors which can form part of the capacitor arrangement according to the invention.

The capacitor arrangement 1 shown in FIG. 1 comprises n capacitors 2.1-2.n arranged in a line. The number of capacitors n is shown in FIG. 1 as 16, but this number should be viewed only as an example and may be both higher and lower. Each capacitor comprises a first outer electrode 3.1-3.n and a second outer electrode 4.1-4.n for charging of the individual capacitors. A feed network (not shown) which operates according to known principles can be used for this charging of the capacitors.

Examples of such a feed network are described, inter alia, in the abovementioned U.S. patent specification. In order to reduce the risk of sparkovers, the first and second outer electrodes are enclosed in a vessel 5 having a fill opening 6 for suitable protective gas such as SF6 gas. In addition to the outer electrodes, the capacitors are each provided with two more electrodes, inner electrodes, disposed in the centre part of the respective capacitor. This electrode arrangement can be more clearly seen from the subsequent description with reference to FIGS. 2a, 2b, 3a, 3b and 3c. The inner electrodes are likewise enclosed in a vessel 9 having a fill tube 10. For the output of electrical pulses generated in the capacitor arrangement 1, a preferably coaxial output 11 is present. The first capacitor 2.1 in the capacitor arrangement is provided with a trigger input 12 for actuating the capacitor arrangement 1.

FIGS. 2a and 2b show a first example of a capacitor 2 which can form part of a capacitor arrangement 1 of the kind described with reference to FIG. 1. The capacitor 2 here consists of two circular perforated metal plates 13, 14 separated by a perforated dielectric 15. The metal plates 13, 14 and the dielectric 15 are in turn coated with an insulating material 16 and the whole may be regarded as a substantially circular-cylindrical body having a central opening 17. Along the outer periphery 18 of the body there are arranged a first and a second outer electrode 3, 4. Preferably, the outer electrodes are arranged in such a way around the periphery of the body that they are separated essentially by 180 degrees. On the inner surface 19 of the body there are arranged inner electrodes 7, 8. These inner electrodes 7, 8 are likewise arranged separated by essentially 180 degrees. As can be seen from FIG. 2b, the inner electrode 7 which is connected to the same metal plate 13 as the outer electrode 3 is orientated such that a maximum distance is generated between the electrodes 3 and 7. The same also applies to the inner electrode 8 connected to the same metal plate 14 as the electrode 4. In the central opening 17, an electrode arrangement is here obtained which has a switch function and which maintains a non-axial discharging process between included electrodes in an arrangement comprising a plurality of capacitors.

FIGS. 3a-3c show a second example of a capacitor 2 which can form part of a capacitor arrangement according to the invention. This involves a coil-shaped arrangement of the actual capacitor function by virtue of the dielectric 15 being enwrapped between two flexible metal foils 13, 14. At one end of the metal foil 13 there is connected a first outer electrode 3, whilst the other end is connected to an inner electrode 7. Correspondingly, the second metal foil 14 is connected at its one end to a second outer electrode 4, whilst the other end is connected to an inner electrode 8. In the centre of the coil-shaped arrangement there is an opening 17. As can best be seen from FIGS. 3b and 3c, both the outer and inner electrodes 3, 4 and 7, 8 are arranged mutually offset in the axial direction. The capacitor, like the capacitor described with reference to FIGS. 2a-2b, is coated with an insulating layer 16.

FIG. 4 shows schematically, via a central section, how the electrodes of individual capacitors 2.1-2.n can be orientated in a line of capacitors. According to the embodiment shown in the figure, corresponding electrodes in the integral capacitors are axially offset in the same way. In the figure, the first inner electrode 7.1-7.n is here offset to the right, whilst the second 8.1-8.n is offset to the left. For the outer electrodes, it simultaneously applies that the first outer electrode 3.1-3.n is offset to the right, whilst the second outer electrode 4.1-4.n is offset to the left. FIG. 4 also shows a method of separating the outer cavity 5 from the inner cavity 9, which two cavities have here been marked schematically with dashed lines. This is achieved by a groove 20 having been formed in the insulating material 16 of the capacitors, in which groove an O-ring 21 has been placed. For the sake of simplicity, the groove and O-ring arrangement is shown for just one junction between two capacitors. Such an arrangement can be introduced, of course, between a plurality of or between all integral capacitors.

The working of the capacitor arrangement is described below with reference to the figures previously described.

For charging of the capacitor arrangement 1, the outer electrodes 3, 4 of the capacitors are connected to a direct-current voltage source (not shown). The large geometric distance between the outer electrodes keeps the electrodes apart and mean that electrical sparkovers are avoided. In order further to reduce the risk of sparkovers, the outer electrodes are enclosed in a cavity containing protective gas. The discharging of the capacitors 2.1-2.1n is initiated by, according to FIG. 1, the first step, that is to say the region between the inner electrode 7.1 of the first capacitor adjoining the nearest adjoining inner electrode 8.2 of the second capacitor, being fed a triggering signal 12. This triggering signal 12 creates a short-circuit between these electrodes, meaning that a switching function passes from the open to the closed position and UV radiation is generated which trips a short-circuit in adjoining inner electrodes between capacitors 2.1-2.n, and the process is repeated throughout the line of capacitors in the centre space. During the discharging of the capacitors, a pulse with high energy density is generated, which is fed to the preferably coaxial output 11.

Alternatively, the capacitor arrangement 1 can be configured with a self-triggering mechanism. In this case, the first step between the first and the second capacitor is configured with a somewhat shorter distance between the electrodes. When the capacitors are charged via the outer electrodes, a short-circuit of the spark gap will be obtained before the capacitors are maximally charged by a self-triggering mechanism. UV radiation is hereupon generated and trips the propagation of short-circuits through the central part of the capacitor arrangement.

The invention is not limited to the embodiments described above by way of example, but can be subjected to modifications within the scope of the following patent claims.

1. Capacitor arrangement comprising at least one capacitor having a first electrode connected to a first conductive element and a second electrode connected to a second conductive element, which first and second conductive elements are separated by a dielectric and which integral capacitors are configured to each form a substantially circular-cylindrical body having a central through opening, characterized in that the first and second conductive elements comprise a further electrode, each respectively defined as the third and fourth electrode, the first and third electrodes being connected to the first conductive element and the second and fourth electrodes being connected to the second conductive element, and the first and second electrodes belonging to a capacitor being placed adjacent to the outer peripheral surface of the body, whilst the third and fourth electrodes are placed adjacent to the central opening of the body.

2. Capacitor arrangement according to claim 1, wherein the first and second electrodes of a capacitor are arranged diagonally on the outer periphery of the body.

3. Capacitor arrangement according to claim 1, wherein the third and fourth electrodes of a capacitor are arranged diagonally on the body in its central opening.

4. Capacitor arrangement according to claim 1, wherein the first and second electrodes of a capacitor and/or the third and fourth electrodes of a capacitor are arranged axially offset.

5. Capacitor arrangement according to claim 1, wherein integral capacitors are arranged in a line in the axial direction and in that a switch element is included in the centre between each of the integral capacitors.

6. Capacitor arrangement according to claim 1, wherein the first and second conductive elements of a capacitor are separated in the axial direction by the dielectric.

7. Capacitor arrangement according to claim 1, wherein the first and second conductive elements of a capacitor are separated in the radial direction by the dielectric.

8. Capacitor arrangement according to claim 7, wherein the first and second conductive elements and the dielectric of a capacitor are configured to form a coil shape.

9. Capacitor arrangement according to claim 1, wherein an outer cavity is arranged to enclose the first and second electrodes of integral capacitors, whilst an inner cavity is arranged to enclose the third and fourth electrodes of integral capacitors.

10. Capacitor arrangement according to claim 1, characterized in that an electric wire with spark gap electrode is connected to each of the third and fourth electrodes for displacement of the spark gap in the axial direction.

11. High-voltage pulse generator comprising a capacitor arrangement according to claim 1.

12. Capacitor arrangement according to claim 2, wherein the third and fourth electrodes of a capacitor are arranged diagonally on the body in its central opening.

13. Capacitor arrangement according to claim 2 wherein the first and second electrodes of a capacitor and/or the third and fourth electrodes of a capacitor are arranged axially offset.

14. Capacitor arrangement according to claim 3 wherein the first and second electrodes of a capacitor and/or the third and fourth electrodes of a capacitor are arranged axially offset.

15. Capacitor arrangement according to claim 2 wherein integral capacitors are arranged in a line in the axial direction and in that a switch element is included in the centre between each of the integral capacitors.

16. Capacitor arrangement according to claim 3 wherein integral capacitors are arranged in a line in the axial direction and in that a switch element is included in the centre between each of the integral capacitors.

17. Capacitor arrangement according to claim 4 wherein integral capacitors are arranged in a line in the axial direction and in that a switch element is included in the centre between each of the integral capacitors.

18. Capacitor arrangement according to claim 2 wherein the first and second conductive elements of a capacitor are separated in the axial direction by the dielectric.

19. Capacitor arrangement according to claim 3 wherein the first and second conductive elements of a capacitor are separated in the axial direction by the dielectric.

20. Capacitor arrangement according to claim 4 wherein the first and second conductive elements of a capacitor are separated in the axial direction by the dielectric.
